(19) United States
(12) Patent Application Publication
(10) Pub. No.: US 2025/0301838 A1
(43) Pub. Date: Sep. 25, 2025

(54) MICRO LED ARRAY

(71) Applicant: JADE BIRD DISPLAY (SHANGHAI) LIMITED, SHANGHAI (CN)

(72) Inventor: Pengfei LI, Shanghai (CN)

(21) Appl. No.: 19/082,232

(22) Filed: Mar. 18, 2025

(30) Foreign Application Priority Data
Mar. 21, 2024 (WO) PCT/CN2024/082891

(51) Int. Cl. H10H 29/14; H10H 29/856

(52) U.S. Cl. CPC H10H 29/142; H10H 29/856

(57) ABSTRACT

A micro LED array having a plurality of micro LED structures, includes: a first semiconductor layer comprising a first mesa array and a first layer formed on the first mesa array, wherein the first mesa array includes a plurality of first mesa structures corresponding to the plurality of micro LED structures and the first layer between adjacent first mesa structures is separated; a continuous light emitting layer formed on the first layer; and a second semiconductor layer comprising a second layer formed on the continuous light emitting layer and a second mesa array provided on the second layer, wherein the second mesa array includes a plurality of second mesa structures corresponding to the plurality of micro LED structures.

### CROSS-REFERENCE TO RELATED APPLICATIONS

The disclosure claims the benefit of priority to PCT Application No. PCT/CN2024/082891, filed on Mar. 21, 2024, which is incorporated herein by reference in its entirety.

### TECHNICAL FIELD

The present disclosure generally relates to micro LED manufacturing technology, and more particularly, to a micro LED array.

### BACKGROUND

Inorganic micro pixel light emitting diodes, also referred to as micro light emitting diodes, micro LEDs, or u-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

Currently, a micro LED display panel with a continuous light emitting layer can be applied to increase the density of the pixels (i.e., the number of micro LEDs per unit area) of the micro LED display panel. However, reducing light crosstalk between adjacent micro LEDs and improving light emission efficiency are still challenges for the micro LED display panel.

### SUMMARY OF THE DISCLOSURE

Embodiments of the present disclosure provide a micro LED array. The micro LED array has a plurality of micro LED structures and includes: a first semiconductor layer comprising a first mesa array and a first layer formed on the first mesa array, wherein the first mesa array includes a plurality of first mesa structures corresponding to the plurality of micro LED structures and the first layer between adjacent first mesa structures is separated; a continuous light emitting layer formed on the first layer; and a second semiconductor layer comprising a second layer formed on the continuous light emitting layer and a second mesa array provided on the second layer, wherein the second mesa array includes a plurality of second mesa structures corresponding to the plurality of micro LED structures.

Embodiments of the present disclosure provide a micro LED array. The micro LED array has a plurality of micro LED structures, and includes: a first semiconductor layer comprising a first mesa array including a plurality of first mesa structures corresponding to the plurality of micro LED structures; a continuous light emitting layer formed on the first mesa array; and a second semiconductor layer formed on the continuous light emitting layer and comprising a second mesa array including a plurality of second mesa structures corresponding to the plurality of micro LED structures. An area of a top surface of the second mesa structure is greater than an area of a bottom surface of the second mesa structure, and an area of a top surface of the first mesa structure is greater than an area of a bottom surface of the first mesa structure.

Embodiments of the present disclosure also provide a micro LED array. The micro LED array has a plurality of micro LED structures and includes: a first semiconductor layer comprising a first mesa array including a plurality of first mesa structures corresponding to the plurality of micro LED structures; a continuous light emitting layer formed on the first semiconductor layer; and a second semiconductor layer formed on the continuous light emitting layer and comprising a second mesa array including a plurality of second mesa structures corresponding to the plurality of micro LED structures. A bottom surface of each of the first mesa structures is an upwardly curved surface.

Embodiments of the present disclosure also provide a micro LED array. The micro LED array has a plurality of micro LED structures and includes: a first semiconductor layer comprising a first mesa array including a plurality of first mesa structures corresponding to the plurality of micro LED structures; a continuous light emitting layer formed on the first semiconductor layer; and a second semiconductor layer formed on the continuous light emitting layer and comprising a second mesa array including a plurality of second mesa structures corresponding to the plurality of micro LED structures. A top surface of each of the second mesa structures is a downwardly curved surface.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1A illustrates a structural cross-sectional diagram of an exemplary micro LED array along an A-A direction shown in FIG. 1B, according to some embodiments of the present disclosure.

FIG. 1B illustrates a structural diagram of a top view of a first semiconductor layer of the micro LED array shown in FIG. 1A, according to some embodiments of the present disclosure.

FIG. 2 illustrates a structural cross-sectional diagram of another exemplary micro LED array, according to some embodiments of the present disclosure.

FIG. 3 illustrates a structural cross-sectional diagram of an exemplary micro LED array, according to some embodiments of the present disclosure.

FIG. 4 illustrates a structural cross-sectional diagram of an exemplary micro LED array, according to some embodiments of the present disclosure.

FIG. 5 illustrates a structural cross-sectional diagram of another exemplary micro LED array, according to some embodiments of the present disclosure.

FIG. 6 illustrates a structural cross-sectional diagram of another exemplary micro LED array, according to some embodiments of the present disclosure.

FIG. 7 illustrates a structural diagram showing a top view of a micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

Embodiments of the present disclosure provide a micro LED array having improved light emission efficiency.

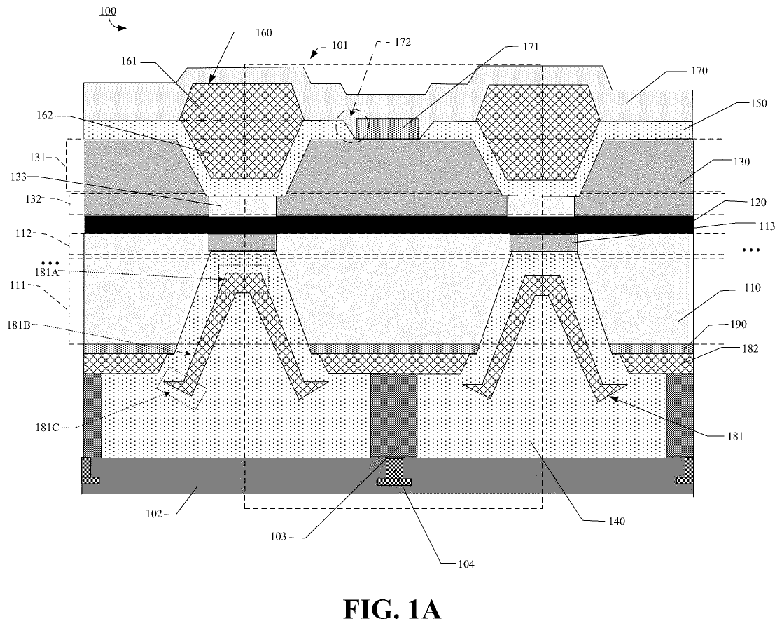

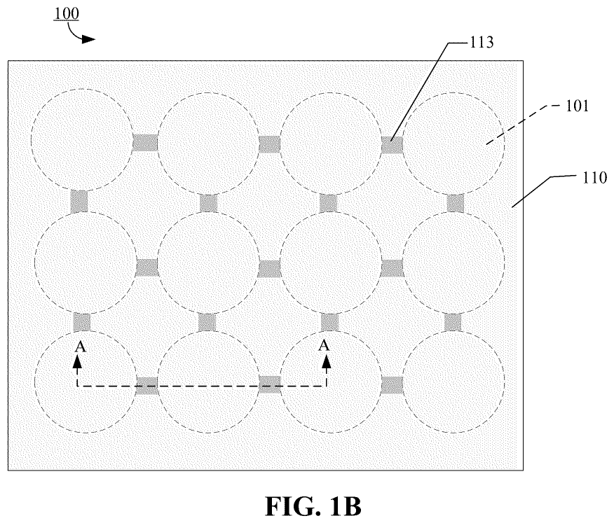

FIG. 1A illustrates a structural cross-sectional diagram of an exemplary micro LED array along an A-A direction shown in FIG. 1B, according to some embodiments of the present disclosure. FIG. 1A shows one complete micro LED structure 101 in the center and two partial micro LED structures to the left and right, respectively, of the center micro LED structure 101. In FIG. 1A, only micro LED structure 101 is described for illustrative purposes. Accordingly, it can be understood that micro LED array 100 may include a plurality of micro LED structures 101. Referring to FIG. 1A, micro LED array 100 includes a first semiconductor layer 110, a continuous light emitting layer 120 formed on first semiconductor layer 110 and a second semiconductor layer 130 formed on continuous light emitting layer 120. First semiconductor layer 110 includes a first mesa array 111 and a first layer 112 formed on first mesa array 111. First mesa array 111 includes a plurality of first mesa structures corresponding to the plurality of micro LED structures 101. More particularly, as shown in FIG. 1A, the plurality of first mesa structures include one complete structure in the center and two partial structures to the left and right, respectively, of the center first mesa structure. Second semiconductor layer 130 includes a second layer 132 formed on continuous light emitting layer 120 and a second mesa array 131 provided on second layer 132. Second mesa array 131 includes a plurality of second mesa structures corresponding to the plurality of micro LED structures 101. More particularly, as shown in FIG. 1A, the plurality of second mesa structures include one complete structure in the center and two partial structures to the left and right, respectively, of the center second mesa structure. A pair of mesa structures, e.g., one of the first mesa structures in first mesa array 111 and a corresponding one of the second mesa structures in second mesa array 131, corresponds to one of micro LED structures 101. As shown in FIG. 1A, first layer 112 between adjacent first mesa structures is separated as further described below and therefore, the crosstalk in first layer 112 between adjacent first micro LED structures is prevented. When one single micro LED structure is lighted, first layer 112 between adjacent micro LED structures is blocked, so that there is no current transmitted to adjacent micro LED structures. As a result, crosstalk between adjacent first mesa structures is prevented. In some embodiments, second layer 132 is also separated between adjacent second mesa structures. As a result, the crosstalk in second layer 132 between adjacent second micro LED structures is prevented.

In some embodiments, first semiconductor layer 110 is a P-type semiconductor layer and second semiconductor layer 130 is an N-type semiconductor layer. In this example, first layer 112 between adjacent first mesa structures is separated by a plurality of N-type semiconductor sub-layers 113. Second layer 132 between adjacent second mesa structures is separated by a plurality of P-type semiconductor sub-layers 133. N-type semiconductor sub-layers 113 are formed by performing N-type doping in corresponding areas of first layer 112. P-type semiconductor sub-layers 133 are formed by performing P-type doping in corresponding areas of second layer 132. FIG. 1B illustrates a structural diagram of a top view of a first semiconductor layer of the micro LED array shown in FIG. 1A, according to some embodiments of the present disclosure. Only for illustrative purposes, as shown in FIG. 1B, the plurality of N-type semiconductor sub-layers 113 are provided in first semiconductor layer 110. Each one of the plurality of N-type semiconductor sub-layers 113 is provided between adjacent micro LED structures 101.

Referring to FIG. 1A, micro LED array 100 further includes a bottom dielectric layer 140 provided under first semiconductor layer 110 and a top dielectric layer 150 formed on a top surface of second semiconductor layer 130. Bottom dielectric layer 140 is further filled between adjacent first mesa structures of first mesa array 111. Micro LED array 100 further includes a plurality of isolation structures 160 provided on top dielectric layer 150 and provided between the adjacent micro LED structures 101. The plurality of isolation structures 160 can prevent light crosstalk between adjacent second mesa structures of second mesa array 131. In some embodiments, one isolation structure 160 includes a top mesa structure 161 and a bottom mesa structure 162. In some embodiments, in the cross-sectional view of FIG. 1A, each of top mesa structure 161 and bottom mesa surface structure 162 has a trapezoidal shape. An area of a top surface of top mesa structure 161 is smaller than an area of a bottom surface of top mesa structure 161. An area of a bottom surface of bottom mesa structure 162 is smaller than an area of a top surface of bottom mesa structure 162. The bottom surface of top mesa structure 161 and the top surface of bottom mesa structure 162 are the same surface. The bottom surface of top mesa structure 161 aligns with a top-most surface of top dielectric layer 150. That is, bottom mesa structure 162 is filled between adjacent second mesa structures, and top mesa structure 161 protrudes from the top-most surface of top dielectric layer 150. Materials of bottom dielectric layer 140 and top dielectric layer 150 can be SiO₂, SiON, Al₂O₃, or SiN, etc. In some embodiments, a material of the plurality of isolation structures 160 is not a metal. For example, the material of isolation structure 160 is an isolation material for absorbing lights.

In some embodiments, micro LED array 100 further includes a top conductive layer 170 formed on tops of top dielectric layer 150 and the plurality of isolation structures 160. In some embodiments, a material of the plurality of top conductive layer 170 can be a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like. Top dielectric layer 150 includes a plurality of openings to expose a portion of the top surface of second mesa structure 130, so that top conductive layer 170 can electrically connect with the plurality of second mesa structures. In some embodiments, a top surface of top conductive layer 170 conforms with the top surface of top dielectric layer 150 and the plurality of isolation structures 160. Accordingly, the top surface of top conductive layer 170 may have an undulating surface. In some other embodiments, the top surface of top conductive layer 170 can be a flat surface.

Micro LED array 100 further includes a plurality of top contact pads 171, each of the plurality of top contact pads 171 being provided on a top surface of a corresponding second mesa structure to electrically connect the top of the corresponding second mesa structure with top conductive layer 170. In this example, the openings in top dielectric layer 150 can accommodate top contact pads 171. In some embodiments, top conductive layer 170 may include a beveled portion 172 defined between a sidewall of top contact pad 171 and top dielectric layer 150. As a result, top conductive layer 170 and top contact pads 171 are in full contact by the top surface and sidewall of top contact pads 171. Therefore, an area of a contact surface between top conductive layer 170 and top contact pads 171 is maximized, thereby increasing the conductivity between top conductive layer 170 and top contact pads 171. In some embodiments, each top contact pad 171 is an ohmic contact layer. In some embodiments, top contact pads 171 and top dielectric layer 150 do not make contact. A material of top contact pad 171 can be metal. In some embodiments, a material of top contact pad 171 may include Al, Au, Rh, Ag, Cr, Ti, Pt, Sn, Cu, etc. The material may also include metal alloys, for example, AuSn, TiW, and the like.

In some embodiments, micro LED array 100 further includes a plurality of first reflective layers 181 provided between the adjacent first mesa structures of first mesa array 111 to reflect light emitted from sidewalls of the first mesa structures. In some embodiments, micro LED array 100 further includes a plurality of second reflective layers 182 provided at bottoms of the plurality of first mesa structures, to reflect light emitted downwards. In some embodiments, each first reflective layer 181 includes a top portion 181A, a side portion 181B, and a bottom portion 181C. Top portion 181A corresponds to an area between adjacent first mesa structures. In some embodiments, top portion 181A has a flat top surface. Side portion 181B is provided around a sidewall of each first mesa structure and fits the sidewall of each first mesa structure. Bottom portion 181C is formed around a bottom of side portion 181B and extends upwards toward a bottom of second reflective layer 182, so that a gap between first reflective layer 181 and second reflective layer 182 can be as small as possible. Bottom portion 181C does not contact with the bottom of second reflective layer 182. Bottom portion 181C of first reflective layer 181 can further reduce the light crosstalk between adjacent mesa structures.

Therefore, provision of reflective layers 181 and 182 reduces light crosstalk between adjacent micro LED structures, and improves light emission efficiency. In some embodiments, materials of the plurality of first reflective layers 181 and the plurality of second reflective layers 182 can be Au, Ag, an omni-directional reflector (ODR), or a distributed Bragg reflector (DBR).

Still referring to FIG. 1A, micro LED array 100 further includes a plurality of bottom contact layers 190 provided between the plurality of second reflective layers 182 and bottoms of the plurality of first mesa structures of first mesa array 111 to improve electrical conductivity between the first mesa structure and the reflective layer. In some embodiments, bottom contact layer 190 is an ohmic contact layer. A material of bottom contact layer 190 may include Al, Au, Rh, Ag, Cr, Ti, Pt, Sn, Cu, etc. The material may also include metal alloys, for example, AuSn, TiW, and the like.

In some embodiments, micro LED array 100 further includes a plurality of bottom connecting structure 103 provided corresponding to the plurality of micro LED structure 101 to electrically connect the plurality of micro LED structure 101 with an integrated circuit (IC) backplane 102. Each bottom connecting structure 103 is provided under a bottom of first mesa structure, for example, bottom connecting structure 103 electrically connects a bottom of second reflective layer 182. IC backplane 102 may further include a plurality of bottom pads 104 corresponding to the plurality of bottom connecting structures 103. One bottom pad 104 electrically connects one bottom connecting structure 103, so that one bottom pad 104 can electrically connect one micro LED structure 101. Therefore, each micro LED structure 101 can be controlled independently.

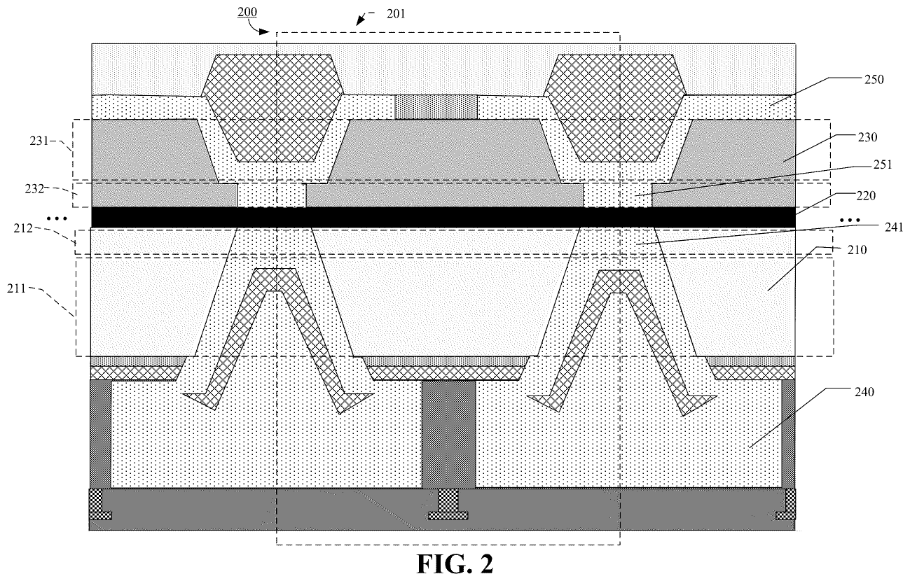

FIG. 2 illustrates a structural cross-sectional diagram of another exemplary micro LED array 200, according to some embodiments of the present disclosure. FIG. 2 shows one complete micro LED structure 201 in the center and two partial micro LED structures to the left and right, respectively, of the center micro LED structure 201. As shown in FIG. 2, similar to micro LED array 100 shown in FIG. 1A, micro LED array 200 includes a first semiconductor layer 210, a continuous light emitting layer 220 formed on first semiconductor layer 210, and a second semiconductor layer 230 formed on continuous light emitting layer 220. First semiconductor layer 210 includes a first mesa array 211 and a first layer 212 formed on first mesa array 211. First mesa array 211 includes a plurality of first mesa structures corresponding to the plurality of micro LED structures. More particularly, as shown in FIG. 2, the plurality of first mesa structures include one complete structure in the center and two partial structures to the left and right, respectively, of the center first mesa structure. Second semiconductor layer 230 includes a second layer 232 formed on continuous light emitting layer 220 and a second mesa array 231 provided on second layer 232. Second mesa array 231 includes a plurality of second mesa structures corresponding to the plurality of micro LED structures. More particularly, as shown in FIG. 2, the plurality of second mesa structures include one complete structure in the center and two partial structures to the left and right, respectively, of the center second mesa structure. Micro LED array 200 further includes a bottom dielectric layer 240 provided under first semiconductor layer 210 and a top dielectric layer 250 formed on a top surface of second semiconductor layer 230. Bottom dielectric layer 240 is further filled between the adjacent first mesa structures of first mesa array 211. In this example, first layer 212 between adjacent first mesa structures is separated by bottom dielectric layer 240. That is, bottom dielectric layer 240 includes a portion 241 further extending to a bottom of continuous light emitting layer 220 to separate the adjacent first mesa structures of first mesa array 211.

Referring to FIG. 2, in some embodiments, second layer 232 between adjacent second mesa structures of second mesa array 231 is separated by top dielectric layer 250. That is, top dielectric layer 250 includes a portion 251 further extending to a top of continuous light emitting layer 220 to separate the adjacent second mesa structures of second mesa array 231.

Description of other features of micro LED array 200 may be found by referring to corresponding features described above with reference to micro LED array 100 shown in FIG. 1A, which will not be repeated here.

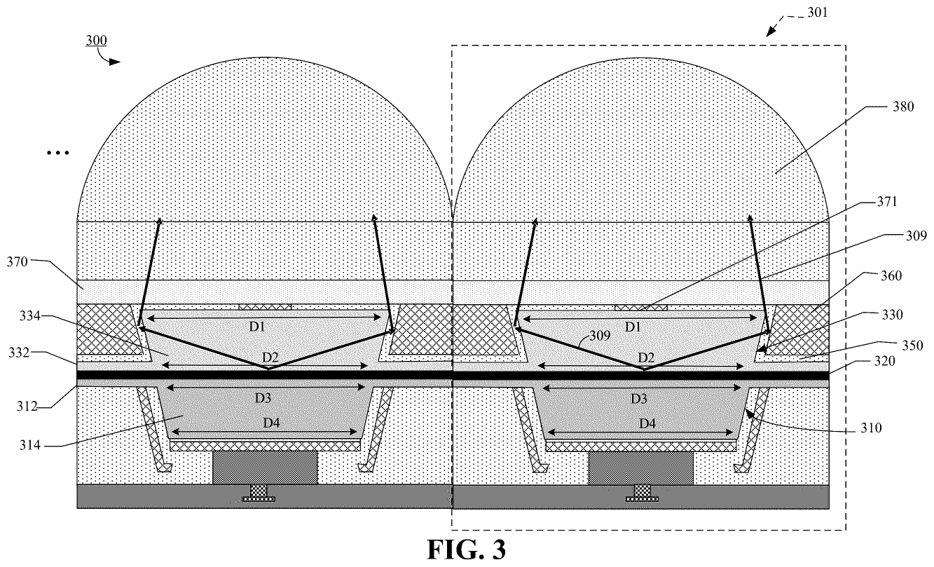

FIG. 3 illustrates a structural cross-sectional diagram of another exemplary micro LED array 300, according to some embodiments of the present disclosure. More particularly, micro LED array 300 includes an array of micro LED structures, and FIG. 3 illustrates a portion of micro LED array 300 including a micro LED structure 301. As shown in FIG. 3, micro LED array 300 includes a first semiconductor layer 310, a continuous light emitting layer 320 formed on first semiconductor layer 310, and a second semiconductor layer 330 formed on continuous light emitting layer 320. First semiconductor layer 310 includes a first mesa array and a first layer 312 formed on first mesa array. First mesa array includes a plurality of first mesa structures 314 (two shown) corresponding to the plurality of micro LED structures 301 (one delineated by broken line). Second semiconductor layer 330 includes a second layer 332 formed on continuous light emitting layer 320 and a second mesa array provided on second layer 332. Second mesa array includes a plurality of second mesa structures 334 (two shown) corresponding to the plurality of micro LED structures 301.

Micro LED array 300 further includes a plurality of isolation structures 360 provided between adjacent second mesa structures 334. An area of a top surface of isolation structure 360 is smaller than an area of a bottom surface of isolation structure 360. The plurality of isolation structures 360 are reflective and can prevent light crosstalk between adjacent micro LED structures. In some embodiments, a material of isolation structures 360 is a metal. As shown in FIG. 3, in this example, an area of a top surface of second mesa structure 334 is greater than an area of a bottom surface of second mesa structure 334 and an area of a top surface of first mesa structure 314 is greater than an area of a bottom surface of the first mesa structure 314. In some embodiments, first mesa structure 314 and second mesa structure 344 have an inverted circular truncated cone structure. That is, a diameter D1 of a top surface of second mesa structure 334 is greater than a diameter D2 of a bottom surface of second mesa structure 334, and a diameter D3 of a top surface of first mesa structure 314 is greater than a diameter D4 of a bottom surface of first mesa structure 314. With this structure, light emitted obliquely from light emitting layer 320, i.e., at an angle other than perpendicular to light emitting layer 320, can be reflected by isolation structure 360 upwards, referring to arrows 309 shown in FIG. 3. Therefore, light emission efficiency can be improved.

In some embodiments, in micro LED structure 301, a sidewall of the corresponding first mesa structure 314 and a sidewall of the corresponding second mesa structure 334 are aligned. That is, as shown in FIG. 3, in the sectional view, the sidewall of first mesa structure 314 and the sidewall of second mesa structure 334 are along a straight line. In some embodiments, sidewalls of isolation structure 360 conform to the sidewalls of the adjacent second mesa structures 334. In some embodiments, micro LED array 300 further includes a top dielectric layer 350 filled between the plurality of second mesa structures 334 and the plurality of isolation structures 360. In some embodiments, top dielectric layer 350 can be SiO₂, SiON, Al₂O₃, or SiN, etc.

In some embodiments, top dielectric layer 350 is further formed on a top of the plurality of second mesa structures 334. In this example, top dielectric layer 350 includes a plurality of openings to expose a portion of top surface of second mesa structure 334. Micro LED array 300 further includes a top conductive layer 370 formed on a top of top dielectric layer 350 and a top of the plurality of isolation structures 360. Top conductive layer 370 connects with the plurality of second mesa structures 334 through the openings in top dielectric layer 350. In some embodiments, micro LED array 300 further includes a plurality of top contact pads 371 provided in the openings to electrically connect second mesa structures 334 with top conductive layer 370. In some embodiments, a material top conductive layer 370 can be a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like.

Still referring to FIG. 3, in some embodiments, micro LED array 300 includes a plurality of lenses 380 (one shown). One lens of the plurality of lenses 380 is provided corresponding to one micro LED structure 301 of micro LED array 300. The lens can adjust light emission angles to improve light emission efficiency.

Description of other features of micro LED array 300 may be found by referring to corresponding features described above with reference to micro LED array 100 shown in FIG. 1A, which will not be repeated here.

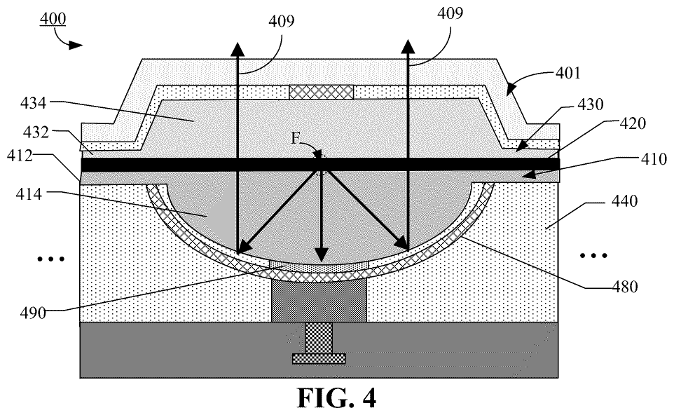

FIG. 4 illustrates a structural cross-sectional diagram of another exemplary micro LED array 400, according to some embodiments of the present disclosure. More particularly, micro LED array 400 includes an array of micro LED structures, and FIG. 4 illustrates a portion of micro LED array 400 including a micro LED structure 401. As shown in FIG. 4, micro LED array 400 includes a first semiconductor layer 410, a continuous light emitting layer 420 formed on first semiconductor layer 410, and a second semiconductor layer 430 formed on continuous light emitting layer 420. First semiconductor layer 410 includes a first mesa array and a first layer 412 formed on first mesa array. First mesa array includes a plurality of first mesa structures 414 (one shown) corresponding to the plurality of micro LED structures 401 (one shown). Second semiconductor layer 430 includes a second layer 432 formed on continuous light emitting layer 420 and a second mesa array provided on second layer 432. The second mesa array includes a plurality of second mesa structures 434 (one shown) corresponding to the plurality of micro LED structures 401 (one shown). As shown in FIG. 4, a bottom surface of first mesa structure 414 is an upwardly curved surface. In some embodiments, the upwardly curved surface is a parabolic surface, and a focus F of the parabolic surface (i.e., bottom surface of first mesa structure 414) is at a plane of continuous light emitting layer 420. Therefore, light emitted from light emitting layer 420 can be reflected outwards as generally parallel light rays as shown by arrows 409 shown in FIG. 4, thereby improving the light emission efficiency. In some embodiments, a corresponding surface of continuous light emitting layer 420 of a corresponding micro LED structure 401 has a circular shape in a top view (not shown), and a center of the circular shape and the focus F of the parabolic surface coincide. That is, the focus F of the parabolic surface is at the center of the circular shape.

In some embodiments, micro LED array 400 further includes a plurality of reflective layers 480 provided under the plurality of first mesa structures 414, each one of plurality of reflective layers 480 corresponds to each one of the plurality of first mesa structures 414. An edge of reflective layer 480 connects with first layer 412. Micro LED array 400 further includes a plurality of bottom contact layers 490 provided between the plurality of reflective layers 480 and bottoms of the plurality of first mesa structures 414 of first mesa array to improve electrical conductivity between first mesa structure 414 and reflective layer 480. In some embodiments, reflective layer 480 connects parts of the bottom of first mesa structure 414 and reflective layer 480, and a bottom dielectric layer 440 fills other parts between the bottom of first mesa structure 414 and reflective layer 480.

Description of other features of micro LED array 400 may be found by referring to corresponding features described above with reference to micro LED array 100 shown in FIG. 1A, which will not be repeated here.

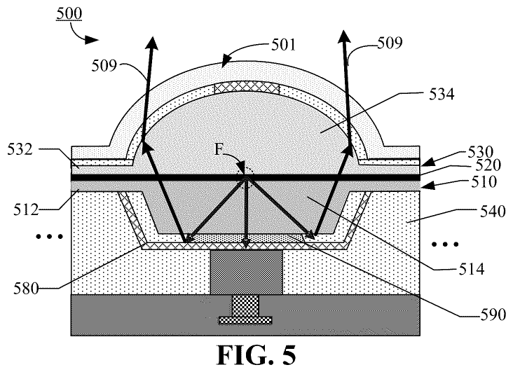

FIG. 5 illustrates a structural cross-sectional diagram of another exemplary micro LED array 500, according to some embodiments of the present disclosure. More particularly, micro LED array 500 includes an array of micro LED structures, and FIG. 5 illustrates a portion of micro LED array 500 including a micro LED structure 501. As shown in FIG. 5, micro LED array 500 includes a first semiconductor layer 510, a continuous light emitting layer 520 formed on first semiconductor layer 510, and a second semiconductor layer 530 formed on continuous light emitting layer 520. First semiconductor layer 510 includes a first mesa array and a first layer 512 formed on first mesa array. First mesa array includes a plurality of first mesa structures 514 (one shown) corresponding to the plurality of micro LED structures 501 (one shown). Second semiconductor layer 530 includes a second layer 532 formed on continuous light emitting layer 520 and a second mesa array provided on second layer 532. Second mesa array includes a plurality of second mesa structures 534 (one shown) corresponding to the plurality of micro LED structures 501 (one shown). As shown in FIG. 5, a top surface of second mesa structure 534 is an upwardly curved surface. In some embodiments, the upwardly curved surface is a parabolic surface, and a focus F of the parabolic surface (i.e., top surface of second mesa structure 534) is at a plane of continuous light emitting layer 520. Therefore, light emitted from light emitting layer 520 can be reflected outwards as converged light rays as shown by arrows 509 shown in FIG. 5, thereby improving the light emission efficiency. In some embodiments, a corresponding surface of continuous light emitting layer 520 of a corresponding micro LED structure 501 has a circular shape in a top view (not shown), and a center of the circular shape and the focus F of the parabolic surface coincide. That is, the focus F of the parabolic surface is at the center of the circular shape.

In some embodiments, micro LED array 500 further includes a plurality of reflective layers 580 provided under the plurality of first mesa structures 514, each one of plurality of reflective layers 580 corresponds to each one of the plurality of first mesa structures 514. An edge of reflective layer 580 connects with first layer 512. In some embodiments, the edge of reflective layer 580 is sealed with first layer 512. Micro LED array 500 further includes a plurality of bottom contact layers 590 provided between the plurality of reflective layers 580 and bottoms of the plurality of first mesa structures 514 of first mesa array to improve electrical conductivity between first mesa structure 514 and reflective layer 580. In some embodiments, reflective layer 580 connects parts of the bottom of first mesa structure 514 and reflective layer 580, and a bottom dielectric layer 540 fills other parts between the bottom of first mesa structure 514 and reflective layer 580.

Description of other features of micro LED array 500 may be found by referring to corresponding features described above with reference to micro LED array 100 shown in FIG. 1A and micro LED array 400 shown in FIG. 4, which will not be repeated here.

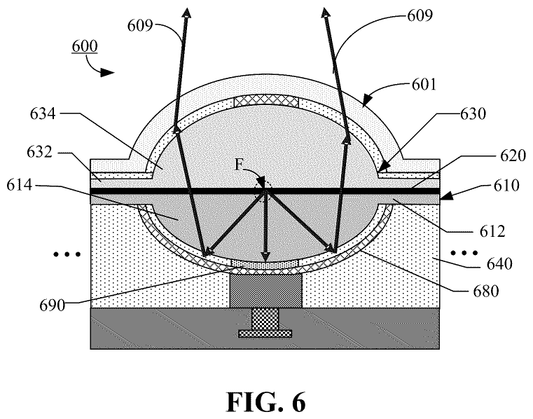

FIG. 6 illustrates a structural cross-sectional diagram of another exemplary micro LED array 600, according to some embodiments of the present disclosure. More particularly, micro LED array 600 includes an array of micro LED structures, and FIG. 6 illustrates a portion of micro LED array 600 including a micro LED structure 601. As shown in FIG. 6, a first semiconductor layer 610 includes a first mesa array and a first layer 612 formed on first mesa array. The first mesa array includes a plurality of first mesa structures 614 (one shown) corresponding to the plurality of micro LED structures 601 (one shown). Second semiconductor layer 630 includes a second layer 632 formed on continuous light emitting layer 620 and a second mesa array provided on second layer 632. Second mesa array includes a plurality of second mesa structures 634 (one shown) corresponding to the plurality of micro LED structures 601 (one shown). As shown in FIG. 6, a top surface of second mesa structure 634 is a downwardly cured surface. In some embodiments, the downwardly curved surface is a parabolic surface. A bottom surface of first mesa structure 614 is an upwardly curved surface. In some embodiments, the upwardly curved surface is a parabolic surface. A focus of the top surface of second mesa structure 634 and a focus of the bottom surface of first mesa structure 614 are coincident and noted as a focus F. The focus F is at a plane of continuous light emitting layer 620. Therefore, light emitted from light emitting layer 620 can be reflected outwards as converged light rays as shown by arrows 609 shown in FIG. 6, thereby improving the light emission efficiency.

In some embodiments, a corresponding surface of continuous light emitting layer 620 of a corresponding micro LED structure 601 has a circular shape in a top view (not shown), and a center of the circular shape and the focus F of the parabolic surfaces overlap. That is, the focus F of the parabolic surfaces is at the center of the circular shape.

In some embodiments, micro LED array 600 further includes a plurality of reflective layers 680 provided under the plurality of first mesa structures 614, each one of plurality of reflective layers 680 corresponds to each one of the plurality of first mesa structures 614. An edge of reflective layer 680 connects with first layer 612. In some embodiments, the edge of reflective layer 680 is sealed with first layer 612. Micro LED array 600 further includes a plurality of bottom contact layers 690 provided between the plurality of reflective layers 680 and bottoms of the plurality of first mesa structures 614 of first mesa array to improve electrical conductivity between first mesa structure 614 and reflective layer 680. In some embodiments, reflective layer 680 connects parts of the bottom of first mesa structure 614 and reflective layer 680, and a bottom dielectric layer 640 fills other parts between the bottom of first mesa structure 614 and reflective layer 680.

Description of other features of micro LED array 600 may be found by referring to corresponding features described above with reference to micro LED array 100 shown in FIG. 1A, micro LED array 400 shown in FIG. 4, and micro LED array 500 shown in FIG. 5, which will not be repeated here.

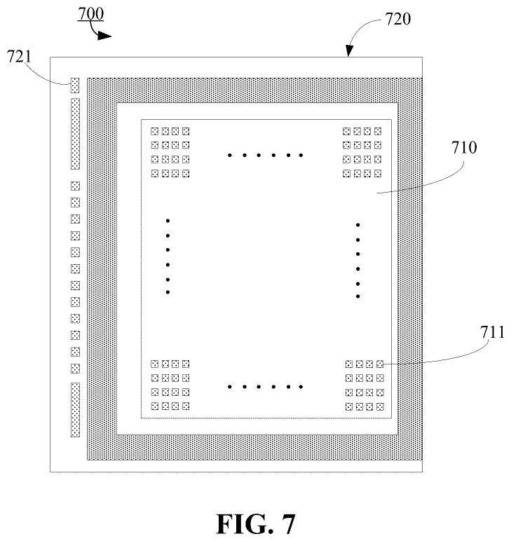

FIG. 7 illustrates a structural diagram showing a top view of a micro LED display panel 700, according to some embodiments of the present disclosure. Referring to FIG. 7, micro LED display panel 700 includes a micro LED array 710 (for example, any one of micro LED arrays 100 to 600 in FIGS. 1A to 6) and an IC (integrated circuit) backplane 720 (e.g., an IC backplane 102 shown in FIG. 1A). Micro LED array 710 is located on IC backplane 720 to form an image display area of micro LED display panel 700. The rest of the area on IC backplane 720 not covered by micro LED array 710 is formed as a non-functional area. IC backplane 720 is formed at the back surface of micro LED array 710 with a part extending outside of, i.e., not covered by, micro LED array 710. Micro LED array 710 includes a plurality of micro LED structures 711 provided in an array. IC backplane 720 is configured to control the plurality of micro LED structures 711. IC backplane 720 may include a bottom pad array (not shown) corresponding to micro LED array 710. The bottom pad array includes a plurality of bottom pads (e.g., a bottom pad 104 shown in FIG. 1A), and one bottom pad corresponds to one micro LED structure 711. One micro LED structure of the plurality of micro LED structures is electrically connected with one bottom pad of the plurality of the bottom pads.

In some embodiments, a top conductive layer (for example, top conductive layer 170 in FIG. 1A) of the micro LED structure is interconnected with each of the plurality of micro LED structures. That is, the top conductive layer is continuously formed on a top of micro LED array 710, and connected with every micro LED structure 711.

In some embodiments, IC backplane 720 further includes a top connected pad 721. The top conductive layer is connected with top connected pad 721, and further may connect to an external circuit.

Each micro LED structure herein (e.g., micro LED structure 101 in FIG. 1A) has a very small volume. The micro LED structure can be applied in a micro LED display panel. The light emitting area of the micro LED display panel, e.g., micro LED display panel 700, is very small, such as 1 mm×1 mm, 3 mm×5 mm, etc. In some embodiments, the light emitting area is the area of the micro LED array in the micro LED display panel. The micro LED display panel includes one or more micro LED structures that form a pixel array in which the micro LED structures are pixels, such as a 1600×1200, 680×480, or 1920×1080-pixel array. The diameter of each micro LED structure is in the range of about 200 nm to 2 μm. An IC backplane, e.g., IC backplane 720, is formed at the back surface of micro LED array 710 and is electrically connected with micro LED array 710. IC backplane 720 acquires signals such as image data from outside via signal lines to control corresponding micro LED structures 711 to emit light or not.

It is understood by those skilled in the art that the micro LED display panel is not limited by the structure described above, and may include greater or fewer components than those illustrated, or some components may be combined, or a different component may be utilized.

The embodiments may further be described using the following clauses:
1. A micro LED array having a plurality of micro LED structures, comprising:
   a first semiconductor layer comprising a first mesa array and a first layer formed on the first mesa array, wherein the first mesa array includes a plurality of first mesa structures corresponding to the plurality of micro LED structures and the first layer between adjacent first mesa structures is separated;
   a continuous light emitting layer formed on the first layer; and
   a second semiconductor layer comprising a second layer formed on the continuous light emitting layer and a second mesa array provided on the second layer, wherein the second mesa array includes a plurality of second mesa structures corresponding to the plurality of micro LED structures.
2. The micro LED array according to clause 1, wherein the second layer between adjacent second mesa structures is separated.
3. The micro LED array according to clause 1 or 2, wherein the first semiconductor layer is a P-type semiconductor layer, the second semiconductor layer is an N-type semiconductor layer, and the first layer between adjacent first mesa structures is separated by a plurality of N-type semiconductor sub-layers.
4. The micro LED array according to clause 3, wherein the second layer between adjacent second mesa structures is separated by a plurality of P-type semiconductor sub-layers.
5. The micro LED array according to clause 1 or 2, further comprising a bottom dielectric layer provided under the first semiconductor layer and filled between the adjacent first mesa structures, wherein the first layer between adjacent first mesa structures is separated by the bottom dielectric layer.
6. The micro LED array according to clause 5, further comprising a top dielectric layer formed on a top surface of the second semiconductor layer, and the second layer between adjacent second mesa structures is separated by the top dielectric layer.
7. The micro LED array according to clause 1, further comprising a top dielectric layer formed on a top surface of the second semiconductor layer and a plurality of isolation structures provided on the top dielectric layer and between adjacent micro LED structures.
8. The micro LED array according to clause 7, wherein each isolation structure has a trapezoidal cross section.
9. The micro LED array according to clause 8, wherein the isolation structure comprises a top mesa structure and a bottom mesa structure, an area of a top surface of the top mesa structure is smaller than an area of a bottom surface of the top mesa structure, an area of a bottom surface of the bottom mesa structure is smaller than an area of a top surface of the bottom mesa structure, the bottom surface of top mesa structure and the top surface of bottom mesa structure are the same surface.
10. The micro LED array according to clause 9, wherein the bottom surface of the top mesa structure aligns with a top-most surface of the top dielectric layer.
11. The micro LED array according to clause 7, further comprising a top conductive layer formed on a top of the top dielectric layer and a top of the plurality of isolation structures, wherein the top dielectric layer comprises a plurality of openings that each expose a portion of a top surface of the second mesa structure and the top conductive layer connects with the plurality of second mesa structures through the openings.
12. The micro LED array according to clause 11, further comprising a plurality of top contact pads provided in the openings to electrically connect the second mesa structure with the top conductive layer.
13. The micro LED array according to clause 12, wherein the plurality of top contact pads are ohmic contact layers.
14. The micro LED array according to clause 12, wherein the top conductive layer comprises a beveled portion filled between a sidewall of the top contact pads and the top dielectric layer.
15. The micro LED array according to clause 14, wherein the top contact pads and top dielectric layer do not make contact.
16. The micro LED array according to clause 1, further comprising a plurality of first reflective layer provided between adjacent first mesa structures to reflect light emitted from sidewalls of the first mesa structures.
17. The micro LED array according to clause 16, further comprising a plurality of second reflective layer provided at bottoms of the plurality of first mesa structures to reflect light emitted downwards.
18. The micro LED array according to clause 17, wherein each first reflective layer comprises a top portion corresponding to an area between adjacent first mesa structures, a side portion formed around a sidewall of the first mesa structure and conforming to the sidewall of the first mesa structure, and a bottom portion formed around a bottom of the side portion and extending upwards to a bottom of the second reflective layer.
19. The micro LED array according to clause 1, wherein a bottom surface of the first mesa structure is a parabolic surface, and a focus of the parabolic surface is at a plane of the continuous light emitting layer.
20. The micro LED array according to clause 19, wherein a top surface of the second mesa structure is a parabolic surface, and a focus of the parabolic surface is at the continuous light emitting layer.
21. The micro LED array according to clause 1, wherein a top surface of the second mesa structure is a parabolic surface, and a focus of the parabolic surface is at the continuous light emitting layer.
22. A micro LED array having a plurality of micro LED structures, comprising:
   a first semiconductor layer comprising a first mesa array including a plurality of first mesa structures corresponding to the plurality of micro LED structures;
   a continuous light emitting layer formed on the first mesa array; and
   a second semiconductor layer formed on the continuous light emitting layer and comprising a second mesa array including a plurality of second mesa structures corresponding to the plurality of micro LED structures;
   wherein an area of a top surface of the second mesa structure is greater than an area of a bottom surface of the second mesa structure, and an area of a top surface of the first mesa structure is greater than an area of a bottom surface of the first mesa structure.
23. The micro LED array according to clause 22, wherein in one micro LED structure, a sidewall of a corresponding first mesa structure and a sidewall of a corresponding second mesa structure are aligned.
24. The micro LED array according to clause 22, further comprising a plurality of isolation structures provided between adjacent second mesa structures, wherein an area of a top surface of an isolation structure is smaller than an area of a bottom surface of an isolation structure.
25. The micro LED array according to clause 24, wherein sidewalls of the isolation structure conform to sidewalls of the adjacent second mesa structures.
26. The micro LED array according to clause 25, further comprising a top dielectric layer filled between the plurality of second mesa structures and the plurality of isolation structures.
27. The micro LED array according to clause 26, wherein the top dielectric layer is further formed on a top of the plurality of second mesa structures, and the top dielectric layer comprises a plurality of openings to expose a portion of a top surface of the second mesa structure; the micro LED array further comprising a top conductive layer formed on a top of the top dielectric layer and tops of the plurality of isolation structures, wherein the top conductive layer connects with the plurality of second mesa structures through the openings.
28. The micro LED array according to clause 27, further comprising a plurality of top contact pads provided in the openings to electrically connect the plurality of second mesa structures with the top conductive layer.
29. The micro LED array according to clause 22, wherein the first semiconductor layer further comprises a first layer formed on the first mesa array, and the continuous light emitting layer formed on the first layer.
30. The micro LED array according to clause 22, wherein the second semiconductor layer further comprises a second layer formed on the continuous light emitting layer, and the second mesa array provided on the second layer.
31. A micro LED array having a plurality of micro LED structures, comprising:
   a first semiconductor layer comprising a first mesa array including a plurality of first mesa structures corresponding to the plurality of micro LED structures;
   a continuous light emitting layer formed on the first semiconductor layer; and
   a second semiconductor layer formed on the continuous light emitting layer and comprising a second mesa array including a plurality of second mesa structures corresponding to the plurality of micro LED structures; wherein a bottom surface of each of the first mesa structures is an upwardly curved surface.
32. The micro LED array according to clause 31, wherein the upwardly curved surface is a parabolic surface, and a focus of the parabolic surface is at a plane of the continuous light emitting layer.
33. The micro LED array according to clause 32, wherein a corresponding surface of the continuous light emitting layer of a corresponding micro LED structure has a circular shape in a top view, and a center of the circular shape and the focus of the parabolic surface coincide.
34. The micro LED array according to clause 31, wherein the first semiconductor layer further comprises a first layer formed on the first mesa array, and the continuous light emitting layer is formed on the first layer.
35. The micro LED array according to clause 34, further comprising a plurality of reflective layers provided under the plurality of first mesa structures, each one of plurality of reflective layers corresponding to each one of the plurality of first mesa structures, and an edge of a reflective layer connecting with the first layer.
36. The micro LED array according to clause 31, wherein a top surface of each of the second mesa structures is a downwardly curved surface.
37. The micro LED array according to clause 36, wherein the downwardly curved surface is a parabolic surface, and a focus of the parabolic surface is at a plane of the continuous light emitting layer.
38. The micro LED array according to clause 37, wherein a corresponding surface of the continuous light emitting layer of a corresponding micro LED structure has a circular shape in a top view, and a center of the circular shape and the focus of the parabolic surface coincide.
39. A micro LED array having a plurality of micro LED structures, comprising:
   a first semiconductor layer comprising a first mesa array including a plurality of first mesa structures corresponding to the plurality of micro LED structures;
   a continuous light emitting layer formed on the first semiconductor layer; and
   a second semiconductor layer formed on the continuous light emitting layer and comprising a second mesa array including a plurality of second mesa structures corresponding to the plurality of micro LED structures; wherein a top surface of each of the second mesa structures is a downwardly curved surface.
40. The micro LED array according to clause 39, wherein the downwardly curved surface is a parabolic surface, and a focus of the parabolic surface is at a plane of the continuous light emitting layer.
41. The micro LED array according to clause 40, wherein a corresponding surface of the continuous light emitting layer of a corresponding micro LED structure has a circular shape in a top view, and a center of the circular shape and the focus of the parabolic surface coincide.
42. The micro LED array according to clause 39, wherein the first semiconductor layer further comprises a first layer formed on the first mesa array, and the continuous light emitting layer formed on the first layer.
43. The micro LED array according to clause 42, further comprising a plurality of reflective layers provided under the plurality of first mesa structures, each one of plurality of reflective layers corresponding to each one of the plurality of first mesa structures, and an edge of a reflective layer connecting with the first layer.
44. The micro LED array according to clause 39, wherein a bottom surface of each of the first mesa structures is an upwardly curved surface.
45. The micro LED array according to clause 44, wherein the upwardly curved surface is a parabolic surface, and a focus of the parabolic surface is at a plane of the continuous light emitting layer.
46. The micro LED array according to clause 45, wherein a corresponding surface of the continuous light emitting layer of a corresponding micro LED structure has a circular shape in a top view, and a center of the circular shape and the focus of the parabolic surface coincide.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED array having a plurality of micro LED structures, comprising:
a first semiconductor layer comprising a first mesa array and a first layer formed on the first mesa array, wherein the first mesa array includes a plurality of first mesa structures corresponding to the plurality of micro LED structures and the first layer between adjacent first mesa structures is separated;
a continuous light emitting layer formed on the first layer; and
a second semiconductor layer comprising a second layer formed on the continuous light emitting layer and a second mesa array provided on the second layer, wherein the second mesa array includes a plurality of second mesa structures corresponding to the plurality of micro LED structures.

2. The micro LED array according to claim 1, wherein the second layer between adjacent second mesa structures is separated.

3. The micro LED array according to claim 1, wherein the first semiconductor layer is a P-type semiconductor layer, the second semiconductor layer is an N-type semiconductor layer, and the first layer between adjacent first mesa structures is separated by a plurality of N-type semiconductor sub-layers.

4. The micro LED array according to claim 3, wherein the second layer between adjacent second mesa structures is separated by a plurality of P-type semiconductor sub-layers.

5. The micro LED array according to claim 1, further comprising a bottom dielectric layer provided under the first semiconductor layer and filled between the adjacent first mesa structures, wherein the first layer between adjacent first mesa structures is separated by the bottom dielectric layer.

6. The micro LED array according to claim 5, further comprising a top dielectric layer formed on a top surface of the second semiconductor layer, and the second layer between adjacent second mesa structures is separated by the top dielectric layer.

7. The micro LED array according to claim 1, further comprising a top dielectric layer formed on a top surface of the second semiconductor layer and a plurality of isolation structures provided on the top dielectric layer and between adjacent micro LED structures.

8. The micro LED array according to claim 7, wherein each isolation structure has a trapezoidal cross section.

9. The micro LED array according to claim 8, wherein the isolation structure comprises a top mesa structure and a bottom mesa structure, an area of a top surface of the top mesa structure is smaller than an area of a bottom surface of the top mesa structure, an area of a bottom surface of the bottom mesa structure is smaller than an area of a top surface of the bottom mesa structure, the bottom surface of top mesa structure and the top surface of bottom mesa structure are the same surface.

10. The micro LED array according to claim 9, wherein the bottom surface of the top mesa structure aligns with a top-most surface of the top dielectric layer.

11. The micro LED array according to claim 7, further comprising a top conductive layer formed on a top of the top dielectric layer and a top of the plurality of isolation structures, wherein the top dielectric layer comprises a plurality of openings that each expose a portion of a top surface of the second mesa structure and the top conductive layer connects with the plurality of second mesa structures through the openings.

12. The micro LED array according to claim 11, further comprising a plurality of top contact pads provided in the openings to electrically connect the second mesa structure with the top conductive layer.

13. The micro LED array according to claim 12, wherein the plurality of top contact pads are ohmic contact layers.

14. The micro LED array according to claim 12, wherein the top conductive layer comprises a beveled portion filled between a sidewall of the top contact pads and the top dielectric layer.

15. The micro LED array according to claim 14, wherein the top contact pads and top dielectric layer do not make contact.

16. The micro LED array according to claim 1, further comprising a plurality of first reflective layer provided between adjacent first mesa structures to reflect light emitted from sidewalls of the first mesa structures.

17. The micro LED array according to claim 16, further comprising a plurality of second reflective layer provided at bottoms of the plurality of first mesa structures to reflect light emitted downwards.

18. The micro LED array according to claim 17, wherein each first reflective layer comprises a top portion corresponding to an area between adjacent first mesa structures, a side portion formed around a sidewall of the first mesa structure and conforming to the sidewall of the first mesa structure, and a bottom portion formed around a bottom of the side portion and extending upwards to a bottom of the second reflective layer.

19. The micro LED array according to claim 1, wherein a bottom surface of the first mesa structure is a parabolic surface, and a focus of the parabolic surface is at a plane of the continuous light emitting layer.

20. The micro LED array according to claim 19, wherein a top surface of the second mesa structure is a parabolic surface, and a focus of the parabolic surface is at the continuous light emitting layer.

21. The micro LED array according to claim 1, wherein a top surface of the second mesa structure is a parabolic surface, and a focus of the parabolic surface is at the continuous light emitting layer.
